(19) United States
(12) Patent Application Publication
(10) Pub. No.: US 2024/0170462 A1
(43) Pub. Date: May 23, 2024

(54) MICRO LIGHT-EMITTING DIODE DISPLAY DEVICE AND MICRO LIGHT-EMITTING DIODE STRUCTURE

(71) Applicant: PlayNitride Display Co., Ltd., Miaoli County (TW)

(72) Inventors: Yun-Li LI, Miaoli County (TW); Yi-Ru HUANG, Miaoli County (TW); Chi-Hao CHENG, Miaoli County (TW); Ching-Liang LIN, Miaoli County (TW)

(21) Appl. No.: 18/427,496

(22) Filed: Jan. 30, 2024

Related U.S. Application Data
(63) Continuation-in-part of application No. 17/517,781, filed on Nov. 3, 2021.

(30) Foreign Application Priority Data
Jun. 21, 2021 (TW) 110122650

(51) Int. Cl. H01L 25/075; H01L 33/62

(52) U.S. Cl. CPC H01L 25/0753; H01L 33/62

(57) ABSTRACT

A micro light-emitting diode display device and a micro light-emitting diode structure. The micro light-emitting diode display device includes a circuit substrate and a plurality of display pixels, the display pixels are arranged on the circuit substrate and are electrically connected with the circuit substrate individually. Each display pixel includes a plurality of series-connection structures, and the light wavelengths of the series-connection structures are different. Each series-connection structure includes at least two micro light-emitting elements, and the light wavelengths of the at least two micro light-emitting elements are within a wavelength range of one color light. The circuit substrate provides a driving voltage to drive the series-connection structures of each display pixel.

### CROSS REFERENCE TO RELATED APPLICATIONS

This application is a Continuation-In-Part (CIP) of an earlier filed, pending, application, having application Ser. No. 17/517,781 and filed on Nov. 3, 2021, which claims priority under 35 U.S.C. § 119(a) on patent application No. 110122650 filed in Taiwan, Republic of China on Jun. 21, 2021, the content of which, including drawings, is expressly incorporated by reference herein.

### BACKGROUND

### Technology Field

The present disclosure relates to a display device and a structure. In particular, the present disclosure relates to a micro light-emitting diode display (LED) device and a micro LED structure.

### Description of Related Art

When the world is paying attention to the future display technology, micro light-emitting diode (micro LED) display device is one of the most promising technologies. In brief, micro LED display device is a technology of miniaturizing and matrixing LED, thereby arranging millions or even tens of millions of dies, which are smaller than 100 microns and thinner than a hair, on a driving substrate.

In order to drive the micro LED display device to emit light, the conventional art is to provide a forward bias (drive voltage) to all electrodes of the micro LEDs through a driving substrate. However, the micro LEDs with different light colors need to be driven by different forward bias. For example, in the driving of the micro LED display device, the forward bias voltage of the micro LED emitting red light is about 1.8 volts, but the forward bias voltages of the micro LEDs emitting green light and blue light are about 3.7 volts. Since the driving substrate needs to provide different drive voltages to the micro LEDs with different light colors, the display device will encounter a problem of relatively high power consumption.

Therefore, it is desired to provide a micro LED display device and a micro LED structure that can have a lower power consumption.

### SUMMARY

One or more exemplary embodiments of this disclosure are to provide a micro light-emitting diode (LED) display device and a micro LED structure that can have a lower power consumption.

In an exemplary embodiment, a micro LED display device of this disclosure comprises a circuit substrate and a plurality of display pixels arranged on the circuit substrate. The display pixels are electrically connected with the circuit substrate individually. Each display pixel comprises a plurality of series-connection structures, and the light wavelengths of the series-connection structures are different. Each series-connection structure comprises at least two micro light-emitting elements, which have light wavelengths within a wavelength range of one color light. The circuit substrate provides a driving voltage to drive the series-connection structures of one of the display pixels.

In an exemplary embodiment, a micro LED display device comprises a circuit substrate, a plurality of display pixels and two electrodes. The display pixels are arranged on the circuit substrate and electrically connected with the circuit substrate individually. Each display pixel comprises a plurality of micro light-emitting elements. In each display pixel, at least two of the micro light-emitting elements form one series-connection structure, and the light wavelengths of the at least two micro light-emitting elements of the series-connection structure are within a wavelength range of one color light. The two electrodes have opposite electrical properties, respectively. The two electrodes are arranged at two of the at least two micro light-emitting elements of one of the series-connection structures, respectively. The circuit substrate drives the at least two micro light-emitting elements of the series-connection structure via the two electrodes.

In an exemplary embodiment, a micro LED structure comprises a temporary substrate, a bonding layer and a plurality of series-connection structures. The bonding layer is arranged on the temporary substrate. The series-connection structures are disposed on the temporary substrate through the bonding layer. Each series-connection structure comprises at least two micro light-emitting elements, and the light wavelengths of the at least two micro light-emitting elements are within a wavelength range of one color light.

As mentioned above, in the micro LED display device of this disclosure, each display pixel comprises a plurality of series-connection structures, and the light wavelengths of the series-connection structures are different. Each series-connection structure comprises at least two micro light-emitting elements, which have light wavelengths within a wavelength range of one color light. The circuit substrate provides a driving voltage to drive the series-connection structures of one of the display pixels. Compared with the conventional micro LED display device having relative high power consumption, the micro LED display device of this disclosure can have relative lower power consumption.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1A is a schematic diagram showing a micro LED display device according to an embodiment of this disclosure.

FIG. 1B is a sectional view of the micro LED display device of FIG. 1A along the line A-A.

FIGS. 2A to 2F are schematic diagrams showing the micro LED display devices of different embodiments of this disclosure.

FIG. 3 is a schematic diagram showing a micro LED display device according to another embodiment of this disclosure.

FIG. 4A is a schematic diagram showing a micro LED display device according to another embodiment of this disclosure.

FIG. 4B is a sectional view of the micro LED display device of FIG. 4A along the line B-B.

FIG. 4C is an enlarged view of one series-connection structure in the display pixel of FIG. 4B.

FIG. 5 is an enlarged view of one series-connection structure in a display pixel according to another embodiment of this disclosure.

FIG. 6 is a schematic diagram showing a display pixel according to another embodiment of this disclosure.

FIG. 7 is a schematic diagram showing a micro LED structure according to an embodiment of this disclosure.

### DETAILED DESCRIPTION OF THE DISCLOSURE

The present disclosure will be apparent from the following detailed description, which proceeds with reference to the accompanying drawings, wherein the same references relate to the same elements.

To be noted, the micro LED display device 1 of this embodiment can be an AM (Active Matrix) or PM (Passive Matrix) micro LED display device, but this disclosure is not limited thereto. In addition, the symbol R, R1 or R2 shown in the following embodiments represents a micro light-emitting element, or a micro light-emitting element emitting red light, the symbol G, G1 or G2 shown in the following embodiments represents a micro light-emitting element, or a micro light-emitting element emitting green light, and the symbol B, B1 or B2 shown in the following embodiments represents a micro light-emitting element, or a micro light-emitting element emitting blue light. The definitions of these symbols depend on the application circumstances and situations. In this disclosure, the micro light-emitting elements are micro LEDs.

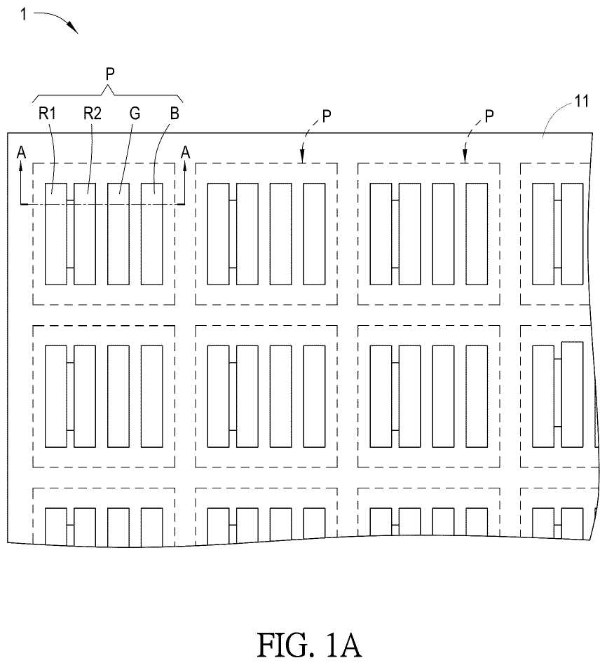

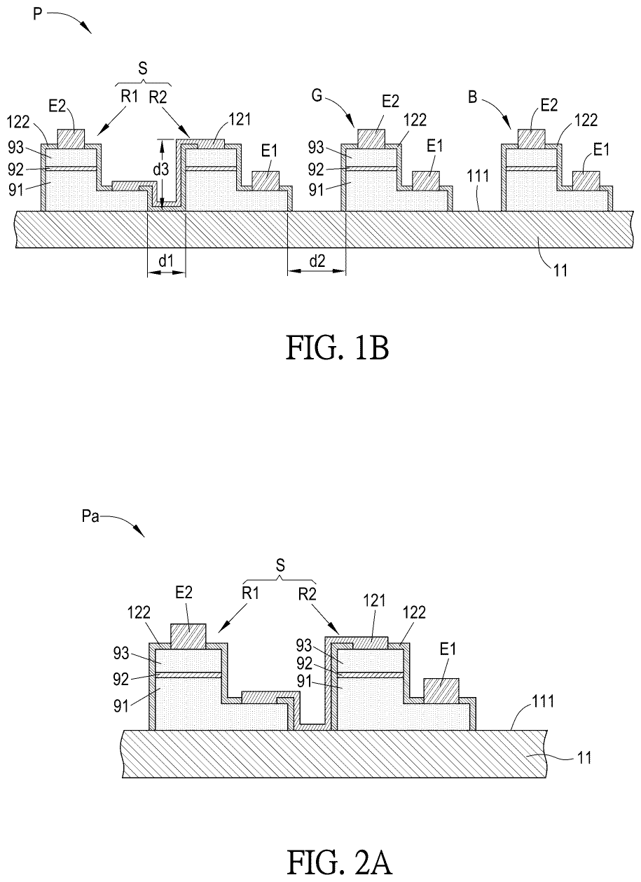

FIG. 1A is a schematic diagram showing a micro LED display device according to an embodiment of this disclosure, and FIG. 1B is a sectional view of the micro LED display device of FIG. 1A along the line A-A. Herein, FIG. 1A shows that the micro LED display device 1 comprises a plurality of display pixels P (or pixel), and FIG. 1B shows the structure of a display pixel P.

Referring to FIGS. 1A and 1B, the micro LED display device 1 comprises a circuit substrate 11 and a plurality of display pixels P, and the display pixels are arranged on the circuit substrate 11. In this embodiment, the pixels P are arranged in a matrix of rows and columns. In this embodiment, the display pixels P are arranged in a matrix including rows and columns and disposed on the circuit substrate 11, and the display pixels P are electrically connected to the circuit substrate 11, respectively. Accordingly, the display pixels P can be driven, through the circuit substrate 11, to emit light of the corresponding colors. Each display pixel P comprises a plurality of micro light-emitting element (i.e. micro LEDs). Herein, each display pixel P comprises at least four micro light-emitting elements. In this embodiment, for example, each display pixel P comprises four micro light-emitting elements R1, R2, G and B. Of course, this disclosure is not limited thereto. In other embodiments, each display pixel P may comprise more than four micro light-emitting elements. For example, each display pixel P may comprise five micro light-emitting elements, such as five micro light-emitting elements R1, R2, G1, G2 and B, or five micro light-emitting elements R1, R2, G, B1 and B2. Of course, each display pixel P may comprise multiple micro light-emitting elements of other numbers and colors.

In some embodiments, the circuit substrate 11 can comprise a plurality of conductive pattern layers and/or circuit layers (not shown), and the circuit substrate 11 can transmit electric signals (e.g. the driving voltage) to the sub-pixels of the display pixels P through the corresponding conductive pattern layers and/or circuit layers for driving the micro light-emitting elements to emit light. In some embodiments, the circuit substrate 11 may be, for example, a Complementary Metal-Oxide-Semiconductor (CMOS) substrate, a Liquid Crystal on Silicon (LCOS) substrate, or a thin film transistor (TFT) substrate, or any of other driving substrates with working circuits, to drive the micro light-emitting elements to emit the corresponding color lights. In some embodiments, the length of the circuit substrate 11 can be, for example but not limited to, less than or equal to 1 inch, and the PPI (pixels per inch) thereof can be greater than 1000. Of course, in other embodiments, the length of the circuit substrate 11 can be greater than 1 inch, and the PPI thereof is not limited.

As shown in FIG. 1B, in each display pixel P, a part of the micro light-emitting elements form at least one series-connection structure S. Herein, the series-connection structure S is composed of at least two micro light-emitting elements, which are connected in series. In this embodiment, the series-connection structure S is composed of two micro light-emitting elements connected in series. In other embodiments, the series-connection structure S can be composed of three or more micro light-emitting elements connected in series (e.g. four micro light-emitting elements connected in series). Specifically, the series-connection structure S of this embodiment comprises two micro light-emitting elements (e.g. R1 and R2), and the wavelengths of the micro light-emitting elements R1 and R2 of the series-connection structure S are within a wavelength range of the same lighting color. Preferably, the difference of wavelengths of the two micro light-emitting elements R1 and R2 is less than 2 nm. This configuration can achieve a better display effect. In this embodiment, the micro light-emitting elements R1 and R2 of the series-connection structure S are configured to emit red light (e.g. having the wavelength between 620 nm and 670 nm). To be noted, this disclosure is not limited thereto. In other embodiments, the micro light-emitting elements included in the series-connection structure S can emit green light or blue light.

The micro light-emitting elements R1, R2, G and B of the display pixels P are arranged on the circuit substrate 11, and each of the micro light-emitting elements R1, R2, G and B comprises a first type semiconductor layer 91, a light-emitting layer 92, and a second type semiconductor layer 93, which are stacked in order. The first type semiconductor layer 91 is disposed on the surface 111 of the circuit substrate 11, and the light-emitting layer 92 is sandwiched between the first type semiconductor layer 91 and the second type semiconductor layer 93. In this embodiment, the light-emitting layer 92 can be, for example, a multiple quantum well (MQW) layer, the first type semiconductor layer 91 can be, for example, an N-type semiconductor, and the second type semiconductor layer 93 can be, for example, a P-type semiconductor. To be noted, this disclosure is not limited thereto. In this embodiment, the micro light-emitting elements R1, R2, G and B of the display pixels P can be horizontal-type micro LEDs, but this disclosure is not limited thereto. In other embodiments, the micro light-emitting elements R1, R2, G and B can be vertical-type micro LEDs or flip-chip type micro LEDs.

In order to drive the micro light-emitting elements R1, R2, G and B to emit light, each of the series-connection structure S and the micro light-emitting elements G and B in each display pixel P is configured with a first electrode E1 and a second electrode E2, which are electrically connected to the circuit substrate 11. In addition, in order to connect the two micro light-emitting elements R1 and R2 in series, the series-connection structure S of this embodiment further comprises a conductive layer 121 and an insulating layer 122. The conductive layer 121 is disposed on the circuit substrate 11 and is configured to connect the two micro light-emitting elements R1 and R2 included in the series-connection structure S in series. The insulating layer 122 is configured between the circuit substrate 11 and a part of the conductive layer 121. In this embodiment, the conductive layer 121 covers a part of the insulating layer 122 and parts of the micro light-emitting elements R1 and R2, and the conductive layer 121 simultaneously electrically connects the first type semiconductor layer 91 of the micro light-emitting element R1 to the second type semiconductor layer 93 of the micro light-emitting element R2. Moreover, on the surfaces of the micro light-emitting elements R1, R2, G and B away from the circuit substrate 11, the regions that are not configured with the first electrode E1, the second electrode E2 or the conductive layer 121 are all covered by the insulating layer 122. This configuration can provide the insulation effect and further protect the micro light-emitting elements R1, R2, G and B from the external moisture and dusts.

To be noted, in each display pixel P of this embodiment, the series-connection circuit (including the conductive layer 121 and the insulating layer 122) for connecting the micro light-emitting elements R1 and R2 in series is arranged between two micro light-emitting elements R1 and R2 instead of disposing on the circuit substrate 11. Thus, the conductive layer 121, the insulating layer 122 and the micro light-emitting elements R1 and R2 can together form the series-connection structure S (i.e., the series-connection structure S comprises the conductive layer 121, the insulating layer 122 and two micro light-emitting elements R1 and R2), which are electrically connected to the circuit substrate 11 via the connection pads (not shown) on the circuit substrate 11. Accordingly, in this embodiment, the series-connection structure can be formed before transferring huge amount of micro light-emitting elements on to the circuit substrate. When the micro light-emitting elements are minimized to the scale of less than 50 μm, the configuration of the series-connection structures can improve the connection between two micro light-emitting elements and increase the production yield of the transferring process. Moreover, since the series-connection structures are composed of the micro light-emitting elements of the same area and are formed before the transferring process, the difference of wavelengths of the micro light-emitting elements included in the same series-connection structure can be smaller (e.g., less than 2 nm). This configuration can achieve a better display effect without sorting the micro light-emitting elements before the transferring process.

In each display pixel P of this embodiment, the first type semiconductor layer 91 of the micro light-emitting element R2 of the series-connection structure S is connected to the first electrode E1, the second type semiconductor layer 93 of the micro light-emitting element R1 of the series-connection structure S is connected to the second electrode E2, and the first electrode E1 and the second electrode E2 are electrically connected to the corresponding connection pads and/or circuit layers of the circuit substrate 11 via additional connective layers (not shown) configured between the electrodes E1 and E2 respectively. Therefore, the driving voltage (a first driving voltage) can be provided from the circuit substrate 11 to the first electrode E1 and the second electrode E2 for driving the micro light-emitting elements R1 and R2 to emit red light. In addition, in each display pixel P of this embodiment, the micro light-emitting elements excluded from the series-connection structure S comprise the micro light-emitting elements G and B. The first type semiconductor layers 91 of the micro light-emitting elements G and B are connected to the first electrode E1, the second type semiconductor layers 93 of the micro light-emitting elements G and B are connected to the second electrode E2, and the first electrode E1 and the second electrode E2 are electrically connected to the corresponding conductive pads and/or circuit layers of the circuit substrate 11 via additional connective layers (not shown) configured between the electrodes E1 and E2 respectively. Therefore, the same driving voltage (a second driving voltage) can be provided from the circuit substrate 11 to the first electrode E1 and the second electrode E2 for driving the micro light-emitting elements G and B to emit green light and blue light, respectively. The configuration of the above-mentioned series-connection structure S can increase the cross voltage between micro light-emitting elements, so that the first driving voltage and the second driving voltage can be the same (e.g. all equal to 3.7 volts).

Therefore, when the micro LED display device 1 is enabled, for example, the second electrode E2 can have a high potential, and the first electrode E1 can have a ground potential or a low potential. The current generated by the potential difference between the second electrode E2 and the first electrode E1 (i.e., the driving voltage) can enable the corresponding series-connection structure S and the micro light-emitting elements G and B excluded from the series-connection structure S to emit the corresponding red light, green light and blue light. More specifically, the micro LED display device 1 can be controlled by the driving element (e.g., an active element such as TFT) of the circuit substrate 11, and the corresponding conductive patterns and/or circuit layers can make the corresponding second electrodes E2 have different height potentials, thereby driving the micro light-emitting elements R1 and R2 included in the series-connection structure S and the micro light-emitting elements G and B excluded from the series-connection structure S to emit light beams of different colors (red, green and blue) and different intensities. The spatial distribution of these light beams with different colors and different intensities can form an image that can be seen by viewers, so that the micro LED display device 1 can function as a full-color display device.

The above-mentioned conductive layer 121 can comprise a metal material, a transparent conductive material, or a combination thereof, but this disclosure is not limited thereto. In this embodiment, the metal material may comprise, for example, aluminum, copper, silver, molybdenum, or titanium, or an alloy thereof, and the transparent conductive material may comprise, for example, indium tin oxide (ITO), indium zinc oxide (IZO), aluminum zinc oxide (AZO), cadmium tin oxide (CTO), tin oxide (SnO₂), zinc oxide (ZnO), or any of other transparent conductive materials. In addition, the above-mentioned insulating layer 122 can be made of an organic material (e.g., a structural photoresist) or an inorganic material (e.g., silicon dioxide or silicon nitride), but this disclosure is not limited thereto.

In some embodiments, in the direction perpendicular to the surface 111 of the circuit substrate 11 (i.e., the top view direction of the circuit substrate 11), the length of each micro light-emitting element (e.g., R1, R2, G or B) can be, for example, less than or equal to 60 μm. In some embodiment, the distance (or pitch) between two micro light-emitting elements (e.g. R1 and R2) of the series-connection structure S is less than the distance between any one of the micro light-emitting elements included in the series-connection structure S and any one of the micro light-emitting elements excluded from the series-connection structure S (e.g. G and B), or between any two of the micro light-emitting elements excluded from the series-connection structure S. In this embodiment, as shown in FIG. 1B, the distance d1 between the micro light-emitting elements R1 and R2 of the series-connection structure S is less than the distance d2 between the micro light-emitting elements R2 and G or the distance between the micro light-emitting elements G and B. In some embodiments, the distance d1 between the micro light-emitting elements (e.g., R1 and R2) of the series-connection structure S can be less than 10 μm, and preferably less than 5 μm, thereby achieving a better display resolution. In some embodiments, the maximum vertical distance d3 between the conductive layer 121 and the surface 111 of the circuit substrate 11 (i.e., the vertical distance between the highest point of the conductive layer 121 and the surface 111 of the circuit substrate 11) is less than or equal to 6 μm, and preferably less than 2 μm. In some embodiments, the wavelengths of the two micro light-emitting elements (e.g., R1 and R2) of the series-connection structure S is greater than the wavelengths of the micro light-emitting elements (e.g., G and B) excluded from the series-connection structure S. In some embodiments, the lighting area of any one of the micro light-emitting elements (e.g., R1 and R2) included in the series-connection structure S is less than or equal to the lighting area of any one of the micro light-emitting elements (e.g., G and B) excluded from the series-connection structure S. In some embodiments, the sum of the lighting areas of the two micro light-emitting elements (e.g., R1 and R2) included in the series-connection structure S is equal to the lighting area of any one of the micro light-emitting elements (e.g., G and B) excluded from the series-connection structure S. In some embodiments, the sum of the lighting areas of the two micro light-emitting elements (e.g., R1 and R2) included in the series-connection structure S is greater than the lighting area of any one of the micro light-emitting elements (e.g., G and B) excluded from the series-connection structure S (this is because that the luminous efficiency of red-light micro light-emitting elements R1 and R2 is relatively lower).

In addition, in each display pixel P of this embodiment, the two red-light micro light-emitting elements R1 and R2 are connected in series, and the green-light and blue-light micro light-emitting elements G and B are individual components (which are not connected to the adjacent micro light-emitting element in series or in parallel). Accordingly, in each display pixel P or display pixels P, the number of the red-light micro light-emitting elements R1 and R2 is greater than the number of the green-light or blue-light micro light-emitting element(s) G or B. For example, the ratio of the numbers of the red, green and blue micro light-emitting elements is 2:1:1. This configuration can provide the optimum display efficiency and decrease the power consumption.

As mentioned above, in the micro LED display device 1 of this embodiment, the micro light-emitting elements R1 and R2 of each display pixel P can form a series-connection structure S, and the wavelengths of the micro light-emitting elements R1 and R2 of the series-connection structure S are within a wavelength range of the same lighting color. In addition, the circuit substrate 11 can respectively provide the same driving voltage to drive the micro light-emitting elements R1 and R2 included in the series-connection structure S and the micro light-emitting elements G and B excluded from the series-connection structure S of each display pixel P. Accordingly, the same driving voltage can not only drive the micro light-emitting elements R1 and R2 included in the series-connection structure S in each display pixel P, but also drive the micro light-emitting elements G and B excluded from the series-connection structure S in each display pixel P. For example, the circuit substrate 11 can provide a 3.7 V driving voltage to the display pixel P for driving the micro light-emitting elements R1 and R2 included in the series-connection structure S to emit red light, driving the micro light-emitting element G excluded from the series-connection structure S to emit green light, and driving the micro light-emitting element B excluded from the series-connection structure S to emit blue light. As a result, comparing with the above-mentioned conventional micro LED display device having relative high power consumption, the micro LED display device 1 of this embodiment can have a relative low power consumption.

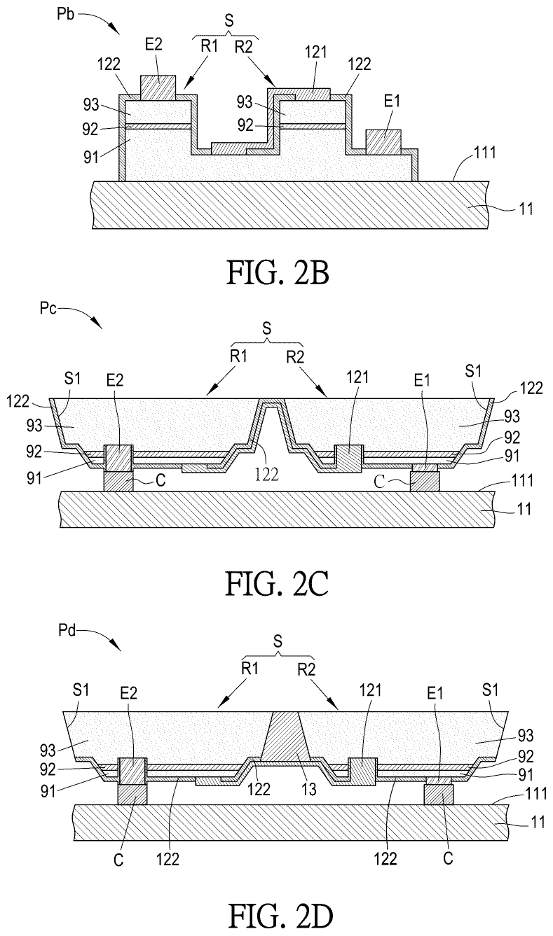

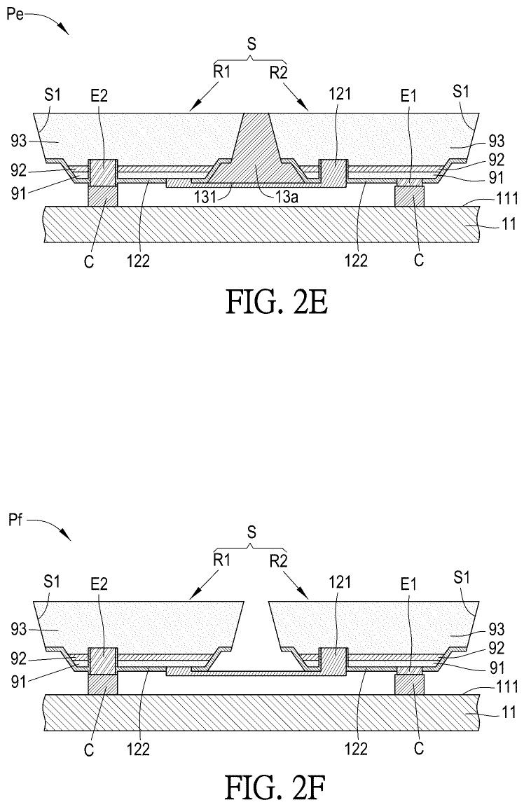

FIGS. 2A to 2F are schematic diagrams showing the micro LED display devices of different embodiments of this disclosure. To be noted, FIGS. 2A to 2F only show the series connection structures of one display pixels Pa-Pf in the micro LED display devices.

As shown in FIG. 2A, the component configurations and connections of the micro LED display device of this embodiment are mostly the same as those of the previous embodiment. Different from the previous embodiment, in each display pixel Pa of the micro LED display device of this embodiment as shown in FIG. 2A, a part of the conductive layer 121 disposed between two micro light-emitting elements R1 and R2 directly contacts the circuit substrate 11. To be noted, in order to prevent the short circuit between the conductive layer 121 and the circuit substrate 11, the circuit substrate 11 must be configured with an insulating material for insulating the conductive layer 121 and the conductive circuit of the circuit substrate 11. In this embodiment, the series-connection structure S can be formed after the two micro light-emitting elements R1 and R2 are transferred to the circuit substrate 11, and this disclosure is not limited thereto.

As shown in FIG. 2B, the component configurations and connections of the micro LED display device of this embodiment are mostly the same as those of the previous embodiment. Different from the previous embodiment, in each display pixel Pb of the micro LED display device of this embodiment as shown in FIG. 2B, the first type semiconductors of the two micro light-emitting elements R1 and R2 of the series-connection structure S are connected to each other. In other words, the micro light-emitting elements R1 and R2 comprise a common first type semiconductor layer 91 (e.g. an N-type semiconductor layer). Since the micro light-emitting elements R1 and R2 are an integrated component, and they are not needed to be separated in advance, so that the pitch between the micro light-emitting elements R1 and R2 can be further reduced. This configuration can improve the usage rate, and increase the connection force during the huge-amount transferring so as to obtain a higher transferring yield. Of course, in different embodiments, the micro light-emitting elements R1 and R2 may comprise a common second type semiconductor layer 93 (e.g. a P-type semiconductor layer), and this disclosure is not limited.

As shown in FIG. 2C, the component configurations and connections of the micro LED display device of this embodiment are mostly the same as those of the previous embodiment. Different from the previous embodiment, in each display pixel Pc of the micro LED display device of this embodiment as shown in FIG. 2C, the micro light-emitting elements R1, R2, G and B are all flip-chip type micro LEDs. Accordingly, the first electrode E1 and the second electrode E2 of the series-connection structure S can be electrically connected to the circuit substrate 11 via the connection pads C on the circuit substrate 11.

Besides, in order to prevent the short circuit between the conductive layer 121 and the flip-chip type micro light-emitting elements R1 and R2 of the series-connection structure S, the series connection design is needed and, moreover, the insulating layer 122 is also required to be configured between the conductive layer 121 and the flip-chip type micro light-emitting elements R1 and R2 before forming the conductive layer 121. In other words, a part of the insulating layer 122 must be disposed between a part of the conductive layer 121 and the micro light-emitting elements R1 and R2 of the series-connection structure S, thereby preventing the short circuit between the conductive layer 121 and the side walls Si of the micro light-emitting elements R1 and R2. In addition, the side walls Si of the micro light-emitting elements R1 and R2 is formed with a stepwise structure. This design can reduce the gaps during the manufacturing process, so that the circuit of the series-connection structure S (the conductive layer 121 and the insulating layer 122) can be formed easier.

As shown in FIG. 2D, the component configurations and connections of the micro LED display device of this embodiment are mostly the same as those of the previous embodiment. Different from the previous embodiment, in each display pixel Pd of the micro LED display device of this embodiment as shown in FIG. 2D, the micro LED display device further comprises a filling structure 13 disposed between the side walls Si of the two micro light-emitting elements R1 and R2 of the series-connection structure S and contacting the side walls Si between the micro light-emitting elements R1 and R2. When the micro light-emitting elements R1 and R2 are smaller than or equal to 50 μm, the bottom half of the stepwise design will reduce the spatial usage rate, so that the filling structure 13 is introduced therebetween. The configuration of the filling structure 13 can reduce the gaps of the micro light-emitting elements R1 and R2, thereby decreasing the difficulty for manufacturing the conductive layer 121 and the insulating layer 122 and increasing the usage rate of the micro light-emitting elements. In some embodiments, the filling structure 13 is made of insulation material. In some embodiments, the filling structure 13 comprises an inorganic material (for example but not limited to silicon dioxide). In some embodiments, the filling structure 13 comprises an organic material (e.g., organic photoresist). In some embodiments, the surface of the filling structure 13 (i.e., the part of the filling structure 13 contacting the micro light-emitting elements R1 and R2) can be configured with a reflective material for forming a light reflection surface, which can increase the light output efficiency of the micro light-emitting elements R1 and R2. In some embodiments, the surface of the filling structure 13 can be configured with a light absorption material (e.g., a black photoresist) for forming a light absorption surface, which can prevent the interference between the outputted light beams. Furthermore, the filling structure 13 can increase the structural supporting force of the micro light-emitting elements R1 and R2, especially during the transferring process, thereby further improving the transferring yield. Moreover, if a light conversion structure (not shown, such as quantum dots) is provided on the micro light-emitting elements R1 and R2 in the following process, the planar upper surface can further improve the manufacturing yield.

As shown in FIG. 2E, the component configurations and connections of the micro LED display device of this embodiment are mostly the same as those of the previous embodiment. Different from the previous embodiment, in each display pixel Pe of the micro LED display device of this embodiment as shown in FIG. 2E, the filling structure 13a is disposed between the side walls Si of the micro light-emitting elements R1 and R2 and further extending toward the circuit substrate 11, so that the surface 131 of the filling structure 13a facing the circuit substrate 11 can be a planar surface. Accordingly, the conductive layer 121 can be easily formed on the planar surface 131. In addition, the filling structure 13a can also increase the structural supporting force of the micro light-emitting elements R1 and R2, especially during the transferring process, thereby further improving the transferring yield. Moreover, if a light conversion structure (not shown, such as quantum dots) is provided on the micro light-emitting elements R1 and R2 in the following process, the planar upper surface can further improve the manufacturing yield.

In addition, after the series-connection structure S is formed, the above-mentioned filling structure 13a (or the filling structure 13) can be removed based on the display requirement so as to remain the empty connection as shown in the display pixel Pf of FIG. 2F.

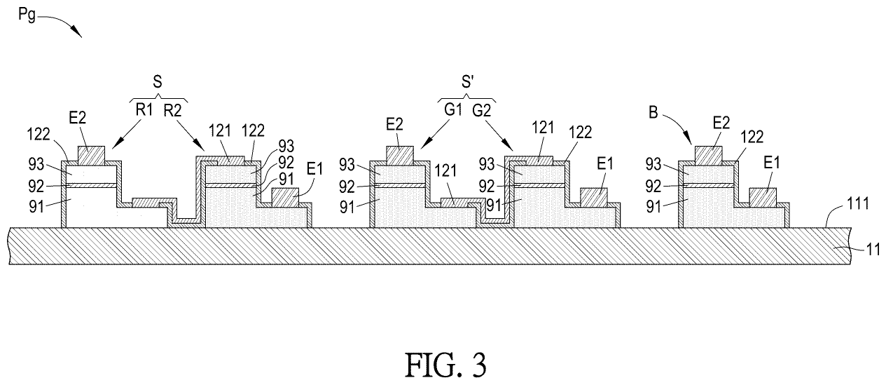

FIG. 3 is a schematic diagram showing a micro LED display device according to another embodiment of this disclosure. To be noted, FIG. 3 only shows the series connection structure of one display pixels Pg in the micro LED display device.

As shown in FIG. 3, the component configurations and connections of the micro LED display device of this embodiment are mostly the same as those of the previous embodiment. Different from the previous embodiment, as shown in FIG. 3, the display pixel Pg of the micro LED display device of this embodiment further comprises another series-connection structure S′. In this embodiment, the series-connection structure S′ comprises a plurality of micro light-emitting elements, which are connected in series. For example, the series-connection structure S′ comprises two micro light-emitting elements G1 and G2 connected in series. The wavelengths of the micro light-emitting elements G1 and G2 of the series-connection structure S′ are within a wavelength range of the same lighting color (e.g., green). Preferably, the difference of wavelengths of the two micro light-emitting elements G1 and G2 is less than 2 nm. Similarly, the circuit substrate 11 can provide the same driving voltage (e.g., 3.7 volts) to drive the micro light-emitting elements included in the series-connection structures S and S′ of each display pixel Pg and the micro light-emitting elements (e.g., the micro light-emitting element B) excluded from the series-connection structures S and S′ of each display pixel Pg. This configuration can achieve the purpose of decreasing the power consumption. In this embodiment, it is unnecessary to design three or more circuits when it is needed to provide the lighting displaying effect (e.g., it needs to enable multiple green micro light-emitting elements to emit green light) and to simultaneously change the circuit design of the circuit substrate to drive the series-connection structures S and S′. As a result, this embodiment can achieve the purpose of decreasing the power consumption and reduce the design difficulty of the driving circuit.

In some embodiments, the two blue-light micro light-emitting elements can construct another series-connection structure. In some embodiments, the two green-light micro light-emitting elements can construct another series-connection structure, and the two blue-light micro light-emitting elements can further construct still another series-connection structure. In some embodiments, the numbers of the micro light-emitting elements connected in series in different series-connection structures of different colors can be the same or different (e.g., four red micro light-emitting elements connected in series, two green micro light-emitting elements connected in series, and two blue micro light-emitting elements connected in series). In some embodiments, the lighting areas of different series-connection structures of different colors can be the same or different, and this disclosure is not limited.

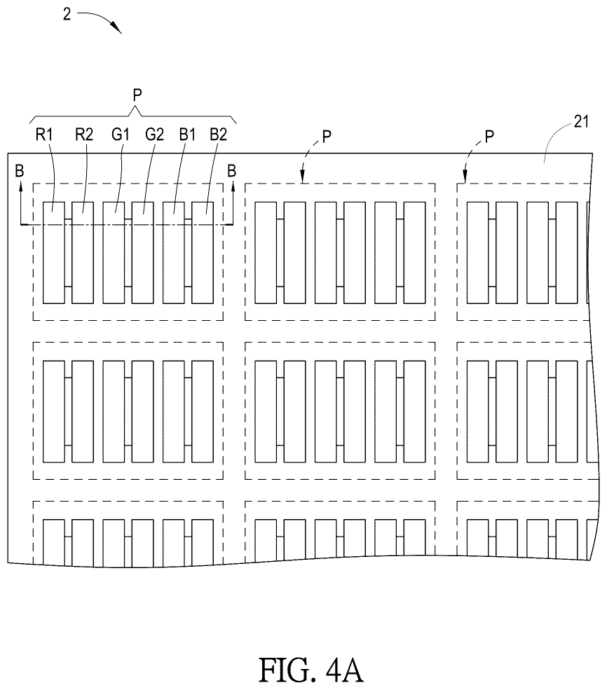

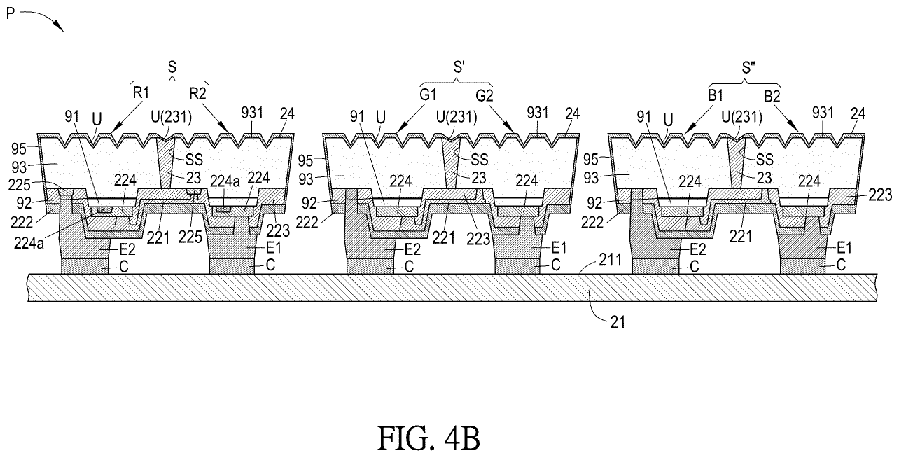

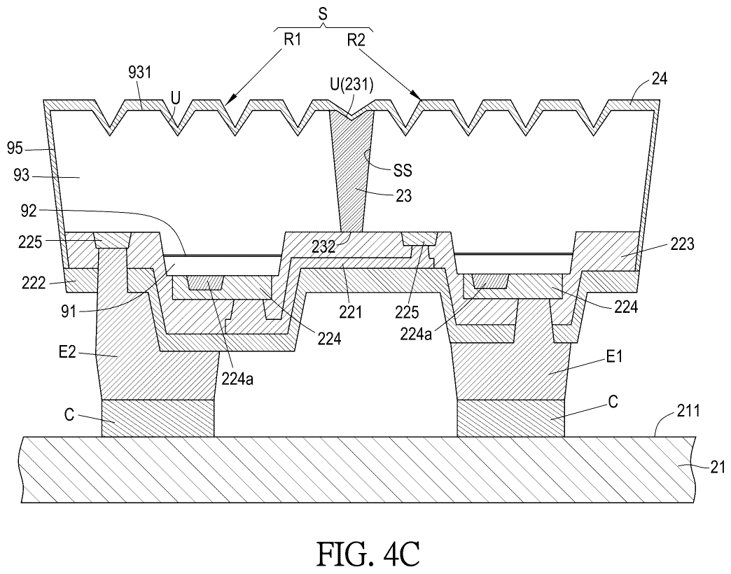

FIG. 4A is a schematic diagram showing a micro LED display device according to another embodiment of this disclosure, FIG. 4B is a sectional view of the micro LED display device of FIG. 4A along the line B-B, and FIG. 4C is an enlarged view of one series-connection structure in the display pixel of FIG. 4B.

Referring to FIGS. 4A to 4C, a micro LED display device 2 of this embodiment includes a circuit substrate 21 and a plurality of display pixels P. The display pixels P are arranged on the circuit substrate 21 and electrically connected with the circuit substrate 21 individually. Each of the display pixels P comprises a plurality of series-connection structures S, S′ and S″, and the light wavelengths of the series-connection structures S, S′ and S″ are different. Each of the series-connection structures S, S′ and S″ comprises at least two micro light-emitting elements having light wavelengths within a wavelength range of one color light.

As shown in FIGS. 4A and 4B, each display pixel P comprises three series-connection structures S, S′ and S″, which include six micro light-emitting elements in total. Specifically, the series-connection structure S comprises two micro light-emitting elements R1 and R2, the series-connection structure S′ comprises two micro light-emitting elements G1 and G2, and the series-connection structure S″ comprises two micro light-emitting elements B1 and B2. In addition, the series-connection structures S, S′ and S″ of each display pixel P can be individually controlled by the circuit substrate 21. In other words, the circuit substrate 21 can provide a driving voltage to drive the series-connection structures S, S′ and S″ of each display pixel P, so that the micro light-emitting elements of the series-connection structures S, S′ and S″ can correspondingly output the red, green and blue lights.

Each display pixel P of the embodiment comprises three series-connection structures S, S′ and S″, but this disclosure is not limited thereto. In other embodiments, each display pixel may comprise different number of series-connection structures. For example, in addition to the two series-connection structures with different light wavelengths, each display pixel P may further comprise an additional micro light-emitting element independent from the series-connection structures, and the light wavelengths of the two series-connection structures are different from that of the additional micro light-emitting element. For example, as shown in the above-mentioned embodiment of FIG. 3, the series-connection structure S of the display pixel Pg comprises micro light-emitting elements R1 and R2, the series-connection structure S′ comprises micro light-emitting elements G1 and G2, and the display pixel Pg further comprises a micro light-emitting element B in addition to the series-connection structures S and S′.

In addition, each of the series-connection structures S, S′ and S″ of this embodiment comprises two micro light-emitting elements. In other embodiments, the series-connection structures with different color lights may optionally comprise different numbers of micro light-emitting element connected in series. Specifically, the series-connection structures of each display pixel P may comprise at least a first series-connection structure and a second series-connection structure. The number of the micro light-emitting elements in the first series-connection structure is different from the number of the micro light-emitting elements in the second series-connection structure. For example, in one embodiment, the series-connection structure S may include three micro light-emitting elements, and the series-connection structure S′ may include two micro light-emitting elements. The numbers of micro light-emitting elements in these series-connection structures, respectively, is not limited to be equal.

Referring to FIGS. 4B and 4C, the two micro light-emitting elements of each of the series-connection structures S, S′ and S″ have a separation space SS, and the width of the separation space SS is less than the width of any one of the two micro light-emitting elements. This configuration can prevent the insufficient structural strength of the series-connection structures S, S′ and S″. In one embodiment, the width of any micro light-emitting element in the series-connection structures S, S′ and S″ can be triple or more of the width of the separation space SS. To be noted, the term “width” in this application is defined to parallel to the surface 211 of the circuit substrate 21.

Moreover, the micro LED display device 2 may further comprise a filling structure 23 disposed in the separation space SS of the at least two micro light-emitting elements of each of the series-connection structures S, S′ and S″. The filling structure 23 of this embodiment is, for example, fully filled in the separation space SS between two micro light-emitting elements. In this case, the top surface 231 of the filling structure 23 has a concave structure U, so that the subsequent film or layer (e.g. the protection layer 24) can be disposed thereon in a better manufacturing yield. In addition, the width of the filling structure 23 gradually increases in the direction away from the circuit substrate 21. In other words, the width of the filling structure 23 is narrower as it is closer to the circuit substrate 21. In an embodiment as shown in FIG. 4C, the ratio of the width of the top surface 231 of the filling structure 23 to the width of the bottom surface 232 of the filling structure 23 may be greater than or equal to 1.5 and less than or equal to 3.

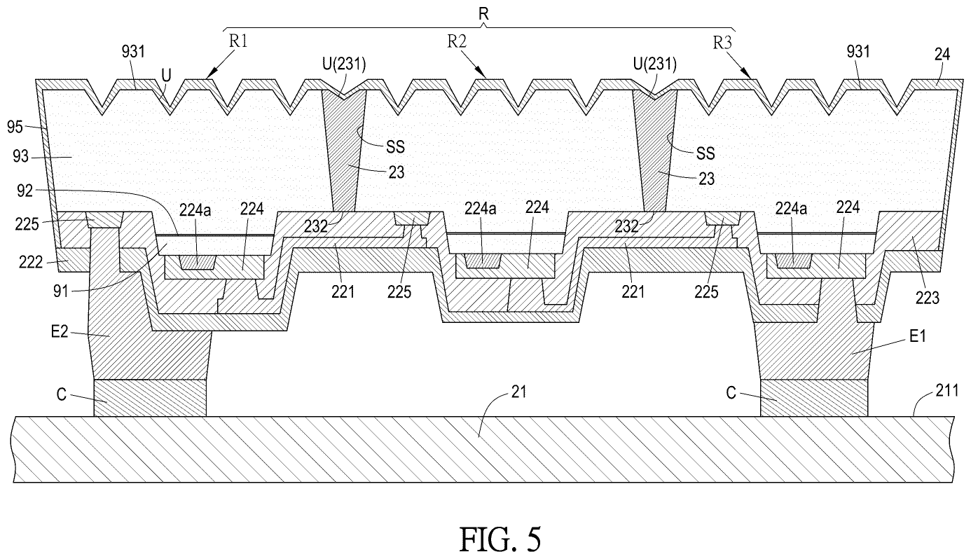

In another embodiment, the number of the micro light-emitting elements in one of the series-connection structures S, S′ and S″ can be greater than 2 (for example but not limited to 3), and the separation space SS is configured between any two of the micro light-emitting elements. For example, as shown in FIG. 5, which is an enlarged diagram of one of the series-connection structures in a display pixel according to another embodiment of this disclosure. In this case, the series-connection structure S as shown in FIG. 5 includes three micro light-emitting elements R1, R2 and R3, which are connected in series. One separation space SS is configured between the micro light-emitting elements R1 and R2, and another separation space SS is configured between the micro light-emitting elements R2 and R3. These two separation spaces SS are both filled with the filling structures 23, respectively.

Referring to FIGS. 4B and 4C, each of the series-connection structures S, S′ and S″ can further include a conductive layer 221, which can electrically connect the at least two micro light-emitting elements of each of the series-connection structures S, S′ and S″ in series. In this case, as shown in FIG. 4C, one end of the conductive layer 221 is electrically connected to the first-type semiconductor layer 91 of the micro light-emitting element R1 through an ohmic contact layer 224, and the other end of the conductive layer 221 is connected to the second-type semiconductor layer 93 of the micro light-emitting element through R2 through another ohmic contact layer 225. Moreover, the series-connection structure S further comprises another ohmic contact layer 224a disposed inside the ohmic contact layer 224. To be noted, the ohmic contact layer 224a and the ohmic contact layer 225 can be omitted in the series-connection structure S′ and the series-connection structure S″.

In addition, each of the series-connection structures S, S′ and S″ can further comprise two electrodes having opposite electrical properties (e.g. a first electrode E1 and a second electrode E2). The first electrode E1 and the second electrode E2 are disposed at the at least two micro light-emitting elements in each of the series-connection structures S, S′ and S″, respectively. Regarding the series-connection structure S, the first electrode E1 is electrically connected with the first-type semiconductor layer 91 of the micro light-emitting element R2 through the ohmic contact layer 224, and the first electrode E1 is further electrically connected with the circuit substrate 21 via the connection pad C. In addition, the second electrode E2 is electrically connected with the second-type semiconductor layer 93 of the micro light-emitting element R1 through the ohmic contact layer 225, and the second electrode E2 is further electrically connected with the circuit substrate 21 via the connection pad C. Therefore, the circuit substrate 21 can drive the micro light-emitting elements R1, R2, G1, G2, B1 and B2 of the series-connection structures S, S′ and S″, through the first electrodes E1 and the second electrodes E2 respectively, to emit light. To be noted, when the number of the micro light-emitting elements in the series-connection structure is n, and n is greater than 2, the series-connection structure includes n light-emitting layers 92 and (n−1) filling structures 23 in total. In addition, the first electrode E1 and the second electrode E2 are electrically connected to the outermost two micro light-emitting elements of the n series-connected micro light-emitting elements, respectively.

In addition, the micro LED display device 2 can further comprise a protection layer 24, which is arranged on the top surface 231 of the filling structure 23 and covers light-outputting surfaces 931 of the micro light-emitting elements R1, R2, G1, G2, B1 and B2 of the series-connection structures S, S′ and S″. In this embodiment, the light-outputting surfaces 931 also have a plurality of concave structures U, so that the subsequent protection layer 24 covering the light-outputting surfaces 931 can have a better manufacturing yield. Moreover, the design of connecting two adjacent micro light-emitting elements with the protection layer 24 can further increase the strength of the series-connection structures S, S′ and S″, thereby avoiding insufficient strength. Furthermore, the protection layer 24 of this embodiment can be further provided on the side walls 95 of two micro light-emitting elements of each series-connection structures S, S′ or S″.

Each of the series-connection structures S, S′ and S″ can further comprise an insulating layer 222, which is disposed between the circuit substrate 21 and the conductive layer 221. In this embodiment, the insulating layer 222 is disposed on the lower surface of each of the series-connection structures S, S′ and S″ and connected with the protection layer 24. In this case, the insulating layer 222 is configured with one or more through holes, so that the first electrode E1 and the second electrode E2 can pass through the through holes for electrically connecting the micro light-emitting elements R1, R2, G1, G2, B1 and B2 to the circuit substrate 21 respectively. In this embodiment, the insulating layer 222 and the protection layer 24 are made of the same material.

In addition, each of the series-connection structures S, S′ and S″ can further comprise a reflective layer 223, which is disposed between the conductive layer 221 and the at least two micro light-emitting elements. The reflective layer 223 is also disposed between the at least two micro light-emitting elements and the insulating layer 222. In this case, the reflective layer 222 includes a material with high reflectivity. Based on the arrangement of the reflective layer 222, the light emitted from the micro light-emitting elements toward the circuit substrate 21 can be reflected and emitted toward the light-emitting surface 931, thereby improving the light outputting rate. The reflective layer 223 of this embodiment is provided with one or more through holes for the conductive layer 221 to pass through, so that the micro light-emitting elements of each of the series-connection structures S, S′ and S″ can be electrically connected in series. In addition, the reflective layer 223 is also provided with additional through hole(s) through which the first electrode E1 and the second electrode E2 can pass, so that the micro light-emitting elements R1, R2, G1, G2, B1 and B2 can be electrically connected with the circuit substrate 21 respectively.

The other technical contents of the display pixels P, the conductive layer 221, the insulating layer 222, the filling structure 23, the first electrode E1, the second electrode E2 and the circuit substrate 21 of the micro LED display device 2 can be referred to the same components of the above-mentioned micro LED display device 1, so the detailed descriptions thereof will be omitted here.

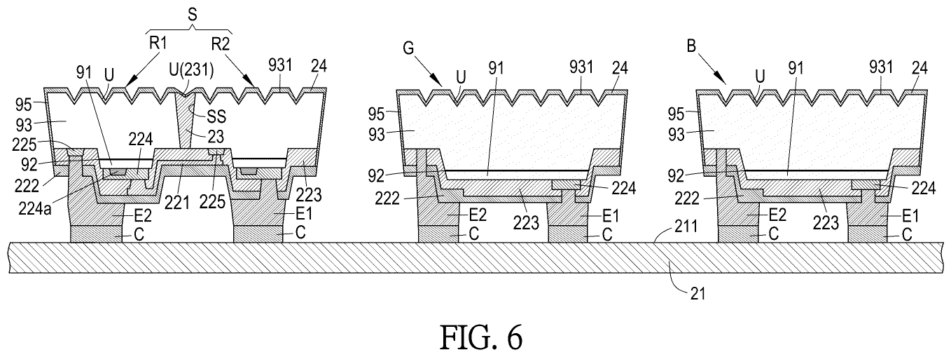

FIG. 6 is a schematic diagram showing a display pixel according to another embodiment of this disclosure. Unlike the display pixel P of FIG. 4B, the display pixel of FIG. 6 only comprises one series-connection structure S. In addition, the display pixel of FIG. 6 further comprises additional micro light-emitting elements G and B independent from the series-connection structure S, and the light wavelength of the series-connection structure S is different from the light wavelengths of the additional micro light-emitting elements G and B. In particular, the series-connection structure S and the additional micro light-emitting elements G and B are all flip-chip components, which can achieve a better transfer bonding yield with the circuit substrate.

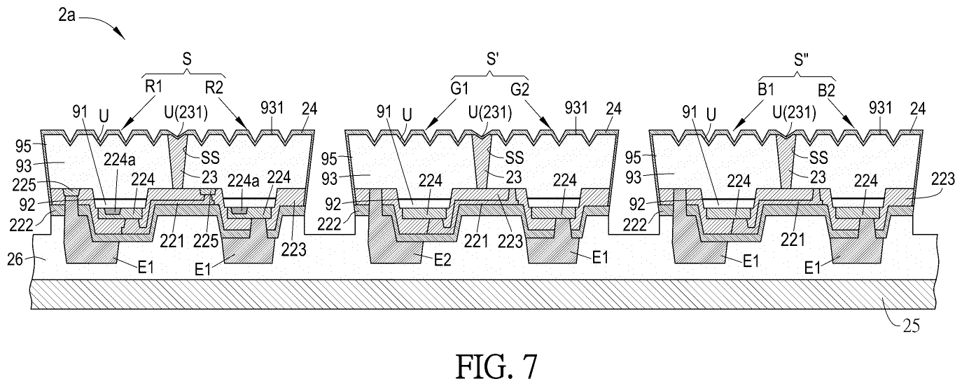

FIG. 7 is a schematic diagram showing a micro LED structure according to an embodiment of this disclosure. The micro LED structure 2a of FIG. 7 is mostly the same as the micro LED display device 2 of FIG. 4B. Unlike the micro LED display device 2, the micro LED structure 2a of FIG. 7 does not comprise the circuit substrate 21. Specifically, in the micro LED structure 2a of this embodiment, a temporary substrate 25 and a bonding layer 26 are provided to substitute the circuit substrate 21, and the series-connection structures S, S′ and S″ are arranged on the temporary substrate 25 through the bonding layer 26. The bonding layer 26 can be an adhesive, which includes, for example, organic materials, for fixing the series-connection structures S, S′ and S″ on the temporary substrate 25. In this embodiment, the micro LED structure 2a of FIG. 7 is a transition structure existing before transferring the series-connection structures S, S′ and S″ to the circuit substrate 21. The temporary substrate 25 is not provided with a driving circuit, and the series-connection structures S, S′ and S″ are bonded to the temporary substrate 25 by the bonding layer 26 (adhesive).

In summary, each display pixel of the micro LED display device comprises a plurality of series-connection structures, and the light wavelengths of the series-connection structures are different. Each series-connection structure comprises at least two micro light-emitting elements, which have light wavelengths within a wavelength range of one color light. The circuit substrate provides a driving voltage to drive the series-connection structures of one of the display pixels. Compared with the conventional micro LED display device having relative high power consumption, the micro LED display device of this disclosure can have relative lower power consumption.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. A micro light-emitting diode display device, comprising:
a circuit substrate; and
a plurality of display pixels arranged on the circuit substrate and electrically connected with the circuit substrate individually, wherein each of the display pixels comprises a plurality of series-connection structures, and light wavelengths of the series-connection structures are different;
wherein, each of the series-connection structures comprises at least two micro light-emitting elements having light wavelengths within a wavelength range of one color light, and the circuit substrate provides a driving voltage to drive the series-connection structures of one of the display pixels.

2. The micro light-emitting diode display device of claim 1, wherein the at least two micro light-emitting elements of each of the series-connection structures have a separation space, and a width of the separation space is less than a width of any one of the at least two micro light-emitting elements.

3. The micro light-emitting diode display device of claim 2, further comprising:
a filling structure disposed in the separation space of the at least two micro light-emitting elements of each of the series-connection structures.

4. The micro light-emitting diode display device of claim 3, wherein a width of the filling structure gradually increases in a direction away from the circuit substrate.

5. The micro light-emitting diode display device of claim 3, further comprising:
a protection layer arranged on a top surface of the filling structure and covering light-outputting surfaces of the at least two micro light-emitting elements of each of the series-connection structures.

6. The micro light-emitting diode display device of claim 5, wherein the protection layer is further arranged on outer side walls of the at least two micro light-emitting elements of each of the series-connection structures.

7. The micro light-emitting diode display device of claim 1, wherein the plurality of series-connection structures at least comprise a first series-connection structure and a second series-connection structure, and a number of the micro light-emitting elements of the first series-connection structure is different from a number of the micro light-emitting elements of the second series-connection structure.

8. The micro light-emitting diode display device of claim 1, wherein each of the series-connection structures further comprises two electrodes having opposite electrical properties, respectively, and the two electrodes are arranged at two of the at least two micro light-emitting elements, respectively.

9. The micro light-emitting diode display device of claim 1, wherein each of the series-connection structures further comprises a conductive layer, and the at least two of the micro light-emitting elements of each of the series-connection structures are connected in series with the conductive layer.

10. The micro light-emitting diode display device of claim 9, wherein each of the series-connection structures further comprises a reflective layer disposed between the conductive layer and the at least two micro light-emitting elements.

11. The micro light-emitting diode display device of claim 9, wherein each of the series-connection structures further comprises an insulating layer arranged between the circuit substrate and the conductive layer.

12. The micro light-emitting diode display device of claim 1, wherein each of the display pixels further comprises an additional micro light-emitting element disposed independent from the series-connection structures, and a light wavelength of the additional micro light-emitting element is different from the light wavelengths of the series-connection structures.

13. A micro light-emitting diode display device, comprising:
a circuit substrate;
a plurality of display pixels arranged on the circuit substrate and electrically connected with the circuit substrate individually, wherein each of the display pixels comprises a plurality of micro light-emitting elements, and wherein, in each of the display pixels, at least two of the micro light-emitting elements form one series-connection structure, and light wavelengths of the at least two micro light-emitting elements of the series-connection structure are within a wavelength range of one color light; and
two electrodes having opposite electrical properties, respectively, wherein the two electrodes are arranged at two of the at least two micro light-emitting elements of one of the series-connection structures, respectively, and the circuit substrate drives the at least two micro light-emitting elements of the one of the series-connection structures via the two electrodes.

14. The micro light-emitting diode display device of claim 13, wherein the one of the series-connection structures comprises three or more of the micro light-emitting elements, and a separation space is configured between any two of the three or more of the micro light-emitting elements.

15. A micro light-emitting diode structure, comprising:
a temporary substrate;
a bonding layer arranged on the temporary substrate; and
a plurality of series-connection structures disposed on the temporary substrate through the bonding layer;
wherein, each of the series-connection structures comprises at least two micro light-emitting elements, and light wavelengths of the at least two micro light-emitting elements are within a wavelength range of one color light.
